(19) United States
(12) Patent Application Publication
(10) Pub. No.: US 2021/0213703 A1
(43) Pub. Date: Jul. 15, 2021

(54) TEXTURED SURFACES HAVING VARIABLE AMOUNTS OF SURFACE ENERGY, METHODS OF MANUFACTURE THEREOF AND ARTICLES COMPRISING THE SAME

(71) Applicant: SHARKLET TECHNOLOGIES, INC., Aurora, CO (US)

(72) Inventors: Ryan Eugene STONEBERG, Aurora, CO (US); Ethan Eugene MANN, Centennial, CO (US)

(73) Assignee: Sharklet Technologies, Inc., Aurora, CO (US)

(21) Appl. No.: 17/054,841

(22) PCT Filed: May 15, 2019
(86) PCT No.: PCT/US2019/032358

§ 371 Date: Nov. 12, 2020

Related U.S. Application Data
(60) Provisional application No. 62/672,223, filed on May 16, 2018.

(51) Int. Cl. B32B 3/30; B32B 9/00; B32B 9/04; B32B 15/08; B32B 37/15; C23C 16/06

(52) U.S. Cl. CPC B32B 3/30; B32B 9/005; B32B 9/041; B32B 9/045; B32B 2439/70; B32B 37/153; C23C 16/06; B32B 2250/02; B32B 15/08

(57) ABSTRACT

Disclosed herein is a multilayered article comprising a first layer having a surface texture on a first surface; and a second layer contacting the surface texture on the first layer; where the surface texture comprises a plurality of identical patterns; each pattern being defined by a plurality of spaced apart features attached to or projected into the first surface, at least one spaced apart feature having a dimension of about 1 nanometer to about 1 millimeter, the plurality of features each having at least one neighboring feature having a substantially different geometry, wherein each pattern has at least one feature which is identical to a feature of a neighboring pattern and shares that feature with the neighboring pattern, wherein an average spacing between adjacent spaced apart features is about 1 nanometer to about 1 millimeter in at least a portion of the first surface, wherein the plurality of spaced apart features are represented by a periodic function.

### BACKGROUND

This disclosure relates to textured surfaces where the texture is used to control the amount of surface energy. It also relates to methods of manufacturing the textured surface and to articles comprising the same. More specifically, it relates to controlling the texture on the surface of a substrate, thus adjusting the adhesion between the substrate and a layer that contacts the surface.

Polymeric films are often used for packaging items of food such as, for example, chips, cookies, vegetables, bread, and the like. It is desirable for these polymeric films to maintain the freshness of the food items contained therein. In order to do so it is desirable to minimize the amount of oxygen and water vapor that contacts the food items. This is accomplished by using multilayered films where one of the layers is a barrier layer that has a very low rates of oxygen and water vapor permeability and diffusion. Metal films are often bonded to the polymeric film to minimize oxygen and water vapor diffusion into the polymeric film.

However, bonding metal films to polymeric films is not very easily accomplished. The polymeric films have to be treated with radiation or with strong acids in order to create a reactive surface that can bond to the metal film. These treatments are expensive and time consuming.

It is therefore desirable to create surfaces (on polymeric substrates) that have different amounts of surface energy. By varying the surface energy of the surface, a variety of different metals, ceramics or polymers can be bonded to the polymer film without the need for pretreatments that involve radiation, plasma or acidic treatments.

### SUMMARY

Disclosed herein is a multilayered article comprising a first layer having a surface texture on a first surface; and a second layer contacting the surface texture on the first layer; where the surface texture comprises a plurality of identical patterns; each pattern being defined by a plurality of spaced apart features attached to or projected into the first surface, at least one spaced apart feature having a dimension of about 1 nanometer to about 100 micrometers, the plurality of features each having at least one neighboring feature having a substantially different geometry, wherein each pattern has at least one feature which is identical to a feature of a neighboring pattern and shares that feature with the neighboring pattern, wherein an average spacing between adjacent spaced apart features is about 1 nanometer to about 1 millimeter in at least a portion of the first surface, wherein the plurality of spaced apart features are represented by a periodic function.

Disclosed herein too is a method comprising texturing a surface of a first layer to produce a textured surface; and disposing a second layer to contact the textured surface of the first layer; where the surface texture comprises a plurality of identical patterns; each pattern being defined by a plurality of spaced apart features attached to or projected into the first surface, at least one spaced apart feature having a dimension of about 1 nanometer to about 100 micrometers, the plurality of features each having at least one neighboring feature having a substantially different geometry, wherein each pattern has at least one feature which is identical to a feature of a neighboring pattern and shares that feature with the neighboring pattern, wherein an average spacing between adjacent spaced apart features is about 1 nanometer to about 1 millimeter in at least a portion of the first surface, wherein the plurality of spaced apart features are represented by a periodic function.

### BRIEF DESCRIPTION OF THE FIGURES

FIG. 1 depicts an article that contains an adhesive bond between two layers that are in contact with each other, where at least one layer is textured to change its surface energy so as to facilitate the formation of the adhesive bond;

FIG. 2(A) depicts one exemplary texture;

FIG. 2(B) depicts another exemplary texture;

FIG. 2(C) depicts another exemplary texture;

FIG. 2(D) depicts another exemplary texture;

FIG. 3(A) depicts an exemplary texture where the features are projected outwards from the surface;

FIG. 3(B) depicts an exemplary texture where the features are projected inwards from the surface;

FIG. 4(A) depicts features having a variable geometry, which are spaced at variable distances from each other;

FIG. 4(B) is another exemplary depiction that shows features having a sinusoidal distribution where the features having a variable geometry have variable spacings between each other;

FIG. 4(C) is another exemplary depiction that shows features having a sinusoidal distribution where the features having a variable geometry have variable spacings between each other;

FIG. 5 shows a texture that has dilational symmetry;

FIG. 6 depicts some of the features that can be changed to change the surface energy to control adhesive bonding with a second layer;

FIG. 7(A) depicts the formation of a pattern formed by features located on opposing surfaces;

FIG. 7(B) depicts another pattern formation formed by features located on opposing surfaces;

FIG. 8 shows directions parallel and perpendicular to the texture that are used to measure the contact angle; the contact angle is measured parallel and perpendicular to the surface;

FIG. 9 shows the shape of the droplet on a) a smooth surface (indicated as SM), b) a surface where the texture is projected into the surface (indicated as ISK-NT) and c) a surface there the texture extends outwards from the surface (indicated as SK10×5); and

FIG. 10 reflects a table which shows the measurements on a variety of different textured surfaces.

### DETAILED DESCRIPTION

Disclosed herein is a multilayered film that comprises a first layer in contact with a second layer at a textured surface. The textured surface can be a surface of the first layer, the second layer or of both the first layer and the second layer. In an embodiment, the first layer and the second layer have textured surfaces at their point of contact. The size and spacing of the features of the textured surface may be varied in order to vary the surface energy of the interface. This may be used to adjust the level of adhesion between the first layer and the second layer.

In an embodiment, the second layer contacts a substantial portion of the texture on the first layer. In an embodiment, the second layer contacts an amount of greater than 90%, preferably greater than 95% of the texture on the first layer.

It is to be noted that the opposing surface of the second layer may also be textured.

The texture can comprise a plurality of spaced features, where the features are arranged in a plurality of groupings (also referred to herein as a “pattern”); the groupings of features being arranged with respect to one another so as to define a tortuous pathway when viewed in a first direction. When viewed in a second direction, the groupings of features are arranged to define a linear pathway.

In one embodiment, when viewed in a second direction, the pathway between the features may be non-linear and non-sinusoidal. In other words, the pathway can be non-linear and aperiodic. In another embodiment, the pathway between the features may be linear but of a varying thickness. The plurality of spaced features may be projected outwards from a surface or projected into the surface. In one embodiment, the plurality of spaced features may have the same chemical composition as the surface. In another embodiment, the plurality of spaced features may have a different chemical composition from the surface. In other words, the features may be bonded to the surface to adjust the surface energy. In another embodiment, the features and the surface may be monolithic (i.e., they form one undivided article).

In an embodiment, the surface texture comprises a plurality of identical patterns; each pattern being defined by a plurality of spaced apart features attached to or projected into the first surface where at least one spaced apart feature having a dimension of about 1 nanometer to about 100 micrometers. The plurality of features each have at least one neighboring feature having a substantially different geometry, wherein each pattern has at least one feature which is identical to a feature of a neighboring pattern and shares that feature with the neighboring pattern. The average spacing between adjacent spaced apart features is about 1 nanometer to about 1 millimeter in at least a portion of the first surface and/or the second surface (which is opposed to the first surface and in contact with it). The plurality of spaced apart features are represented by a periodic function.

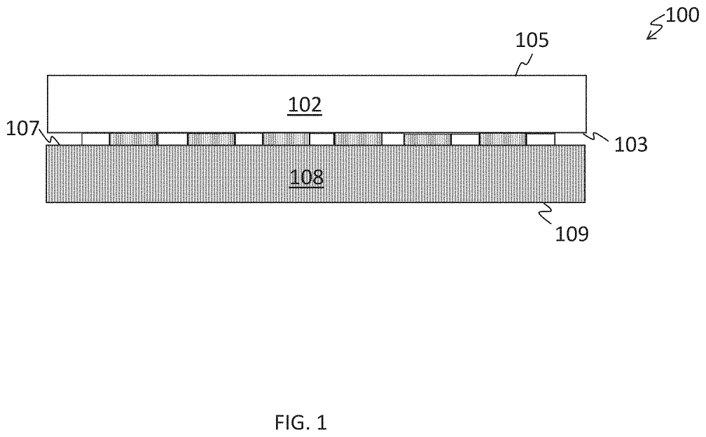

FIG. 1 depicts an article 100 that contains an adhesive bond between two layers 102 and 108 that are in contact with each other. With reference now to the FIG. 1, the first layer 102 has a first surface 103 and a second surface 105 (that is opposed to the first surface 103), while the second layer 108 has a first surface 107 and a second surface 109 (that is opposed to the first surface 107). The first surface 103 of the first layer 102 is in contact with the first surface 107 of the second layer 108.

As can be seen in the FIG. 1, the respective first surfaces are textured. In other words, the first surface 103 of the first layer 102 and the first surface 107 of the second layer 108 are textured and in contact with each other. By changing the size, geometry and the spacing between the features the strength of the adhesive bond can be varied depending upon the application. It is to be noted that the second surface 105 may also be textured to change its surface energy. This is not depicted in the FIG. 1.

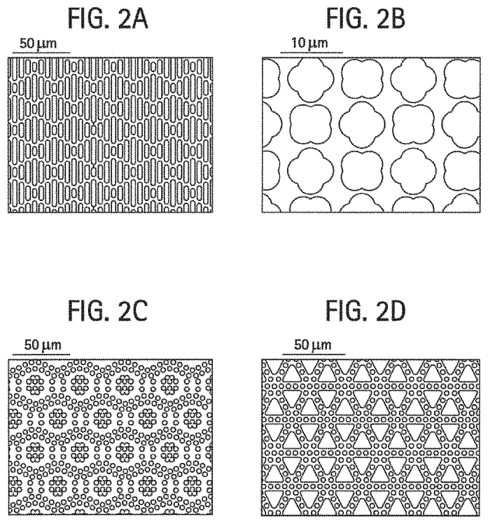

The FIG. 2 depicts various features that can be used to texture the surface. FIG. 2(A) depicts a plurality of elongated pillars of different sizes disposed on the surface of a layer (also referred to as a substrate) to produce the surface texture. FIG. 2(B) depicts pillars having a cross-sectional area that is obtained by combining squares and semi-circles. FIG. 2(C) combines circular pillars and partial clubs. FIG. 2(D) combines pillars having a triangular cross-section with pillars having a circular cross-section.

In this manner features having a variety of cross-sectional geometries such as, for example, square, rectangular, triangular, polygonal, circular, semi-circular may be combined to produce a variety of patterns. By varying the size, the geometry and the distance between the features, the surface energy may be varied.

As seen in the FIGS. 2(A)-2(D), the features may be arranged in the form of a pattern. The features are arranged in a plurality of groupings; the groupings of features comprise repeat units. The repeat unit is also referred to as a pattern. The spaced features within a grouping are spaced apart at an average distance of about 10 nanometers to about 1 millimeter. The groupings of features are arranged with respect to one another so as to define a tortuous pathway, the groupings have patterns of features wherein one or more features are shared between groupings. These are generally referred to as shared features. The plurality of spaced features may extend outwardly from a surface or may be pressed into the surface (i.e., they extend into the surface of the substrate).

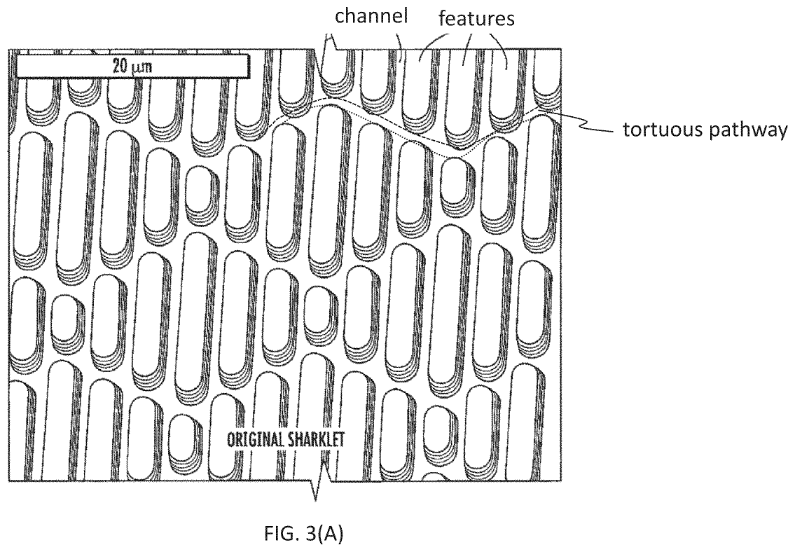

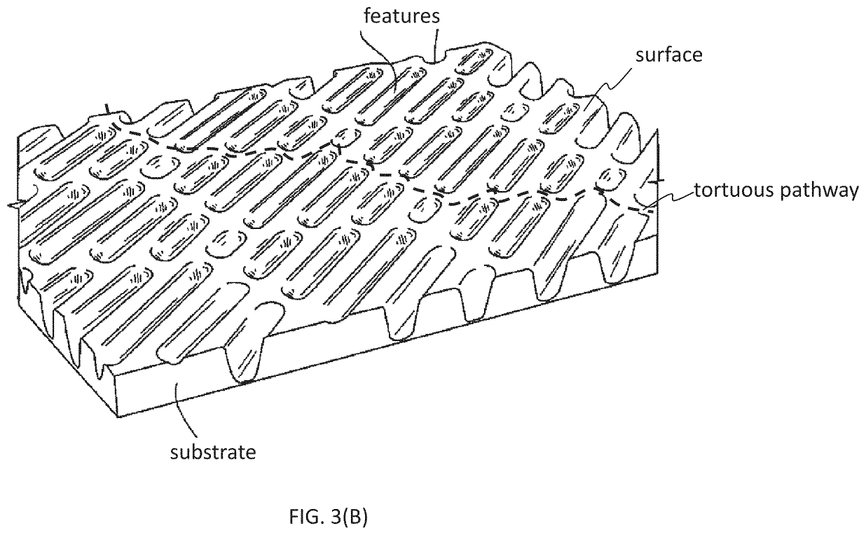

FIGS. 3(A) and 3(B) depict textures surfaces where the features extend outwardly from the surface (FIG. 3(A)) or have a plurality of features projecting into the surface of a substrate (FIG. 3(B)).

In one embodiment, a sum of a number of features shared by two neighboring groupings is equal to an odd number. In another embodiment, a sum of a number of features shared by two neighboring groupings is equal to an even number.

The number of features in a given pattern can be odd or even. In one embodiment, if the total number of features in a given pattern are equal to an odd number, then the number of shared features are generally equal to an odd number. In another embodiment, if the total number of features in a given pattern are equal to an even number, then the number of features in the given pattern are equal to an even number.

In one embodiment, the plurality of spaced features has a similar chemical composition to the surface. In another embodiment, the plurality of spaced features has a different chemical composition from that of the surface. In one embodiment, the features have similar geometries, while in another embodiment, the features can have different geometries. The groupings may show dilational symmetry.

In an embodiment, the plurality of spaced features is applied to the surface in the form of a coating and can comprise an organic polymer, a ceramic or a metal. Alternatively, the individual features may be deposited on the surface and may not be connected to each other. These individual features may comprise an organic polymer, a ceramic or a metal. As noted above, the groupings of features (i.e., the pattern) are arranged with respect to one another so as to define a linear pathway or a plurality of channels. The tortuous pathway is defined by a sinusoidal function.

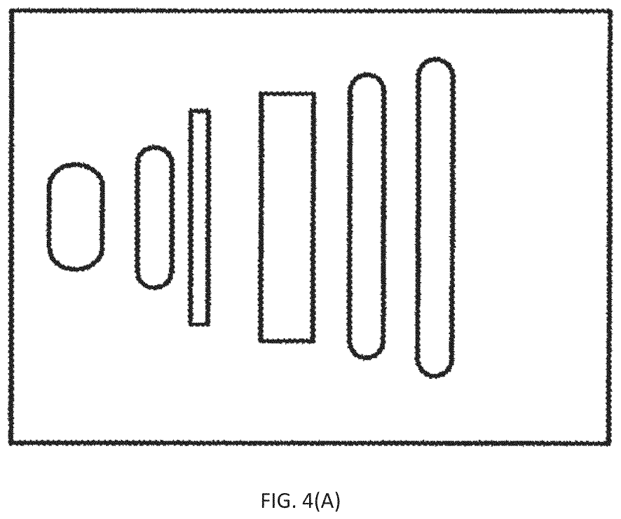

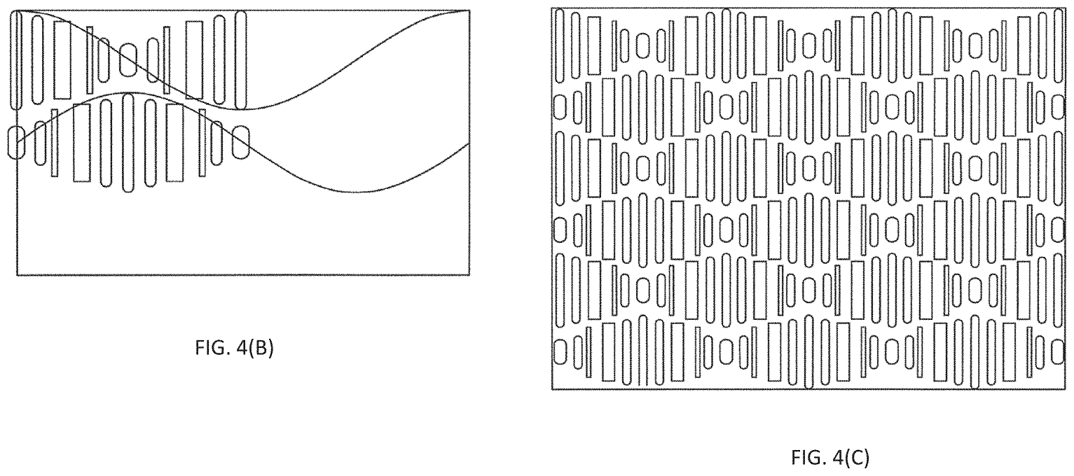

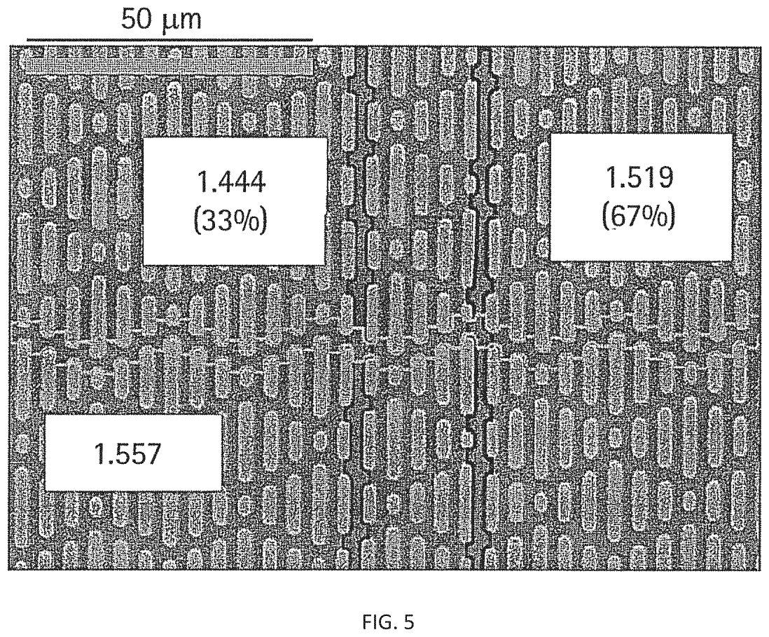

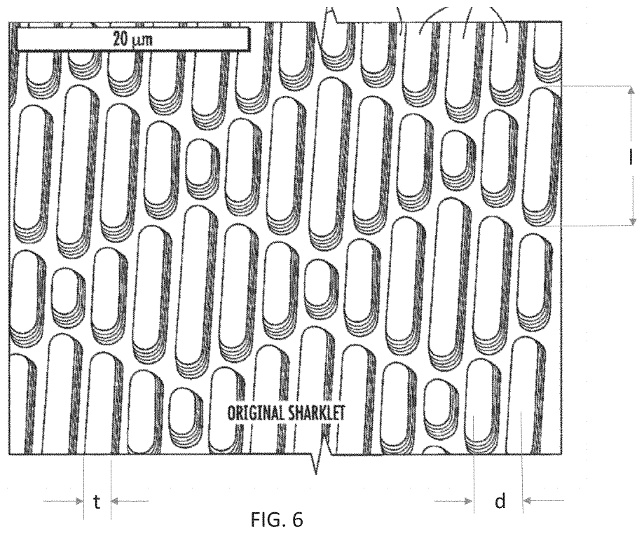

The spaced features can have variety of geometries and can exist in one, two or three dimensions or any dimensions therebetween. The spaced features can have similar geometries with different dimensions or can have different geometries with different dimensions. For example, in the FIG. 3(A), the spaced features are of a similar shape, with each shape having a different sizes, while in the FIGS. 4(A), 4(B) and 4(C), the spaced features have different geometries and different dimensions.

The geometries can be regular (e.g., described by Euclidean mathematics) or irregular (e.g., described by non-Euclidean mathematics). Euclidean mathematics describes those structures whose mass is directly proportional to a characteristic dimension of the spaced feature raised to an integer power (e.g., a first power, a second power or a third power). In one embodiment, the geometries can comprise shapes that are described by Euclidean mathematics such as, for example, lines, triangles, circles, quadrilaterals, polygons, spheres, cubes, fullerenes, or combinations of such geometries.

For example, the FIGS. 3(A) and 3(B) show that the spaced features are almost elliptical, i.e., the cross-sectional geometry of each feature when viewed from the top-down is similar to that which could be obtained by combining rectangles with semi-circles. Similarly, the FIGS. 2(B), 2(C) and 2(D) show features that comprise circles, sections of circles (e.g., semi-circles, quarter-circles), triangles, and the like.

In one embodiment, a repeat unit can be combined with a neighboring repeat unit so as to produce a combination of spaced apart features that have a geometry that is described by Euclidean mathematics. As can be seen in the FIGS. 2(C) and 2(D), the respective repeat units can be combined to produce different geometries. For example in the FIG. 2(D), the repeat unit can be combined with a single neighboring repeat unit to produce a diamond shaped geometry. Similarly, 3 or more neighboring repeat units can be combined to produce a rhombohedral, while six repeat units can be combined to produce a hexagon. Thus repeat units may be combined to produce structures whose geometries can be described by Euclidean mathematics.

In one embodiment, the spaced features can have irregular geometries that can be described by non-Euclidean mathematics. Non-Euclidean mathematics is generally used to describe those structures whose mass is directly proportional to a characteristic dimension of the spaced feature raised to a fractional power (e.g., fractional powers such as 1.34, 2.75, 3.53, or the like). Examples of geometries that can be described by non-Euclidean mathematics include fractals and other irregularly shaped spaced features.

In one embodiment, spaced features whose geometries can be described by Euclidean mathematics may be combined to produce features whose geometries can be described by non-Euclidean mathematics. In other words, the groupings of features can have dilational symmetry. The fractal dimension can be measured perpendicular to the surface upon which the features are disposed or may be measured parallel to the surface upon which the features are disposed. The fractal dimensions are measured in the inter-topographical gaps.

In one embodiment, the fractal dimensions can have fractional powers of about 1.00 to about 3.00, specifically about 1.25 to about 2.25, more specifically about 1.35 to about 1.85 in a plane measured parallel to the surface upon which the features are disposed. In another embodiment, the fractal dimensions can have fractional powers of about 1.00 to about 3.00, specifically about 1.25 to about 2.25, more specifically about 1.35 to about 1.85 in a plane measured perpendicular to the surface upon which the features are disposed.

In yet another embodiment, the fractal dimensions can have fractional powers of about 3.00 to about 4.00, specifically about 3.25 to about 3.95, more specifically about 3.35 to about 3.85 in a plane measured perpendicular to the surface upon which the features are disposed. In other words, the tortuous pathway or the surface of each feature may be textured with features similar to those of the pattern (albeit on a smaller scale), thus creating micro-tortuous pathways and nano-tortuous pathways within the tortuous pathway itself.

In another embodiment, the spaced features may have multiple fractal dimensions in a direction parallel to the surface upon which the features are disposed. The spaced features may be arranged to have 2 or more fractal dimensions, specifically 3 or more dimensions, specifically 4 or more dimensions in a direction parallel to the surface upon which the features are disposed. As can be seen in the FIG. 5, the features have 3 different fractal dimensions in a plane parallel to the surface upon which the features are disposed. The fractal dimensions created by the features in a direction from the top to the bottom of the micrograph are 1.444 and 1.519 respectively, while the fractal dimension created by the features in a direction from left to right have dimensions of 1.557.

In an embodiment, with reference now once again to the FIG. 1, the opposing surfaces 103 and 107 can have images that are negative images of each other. In other words, the first surface 103 contains features that are outwardly projected while the surface 107 contains inwardly projected features to accommodate the outward projected features of surface 103. Similarly, the surface 103 may contain inwardly projected features to accommodate the outwardly projected features of the surface 107.

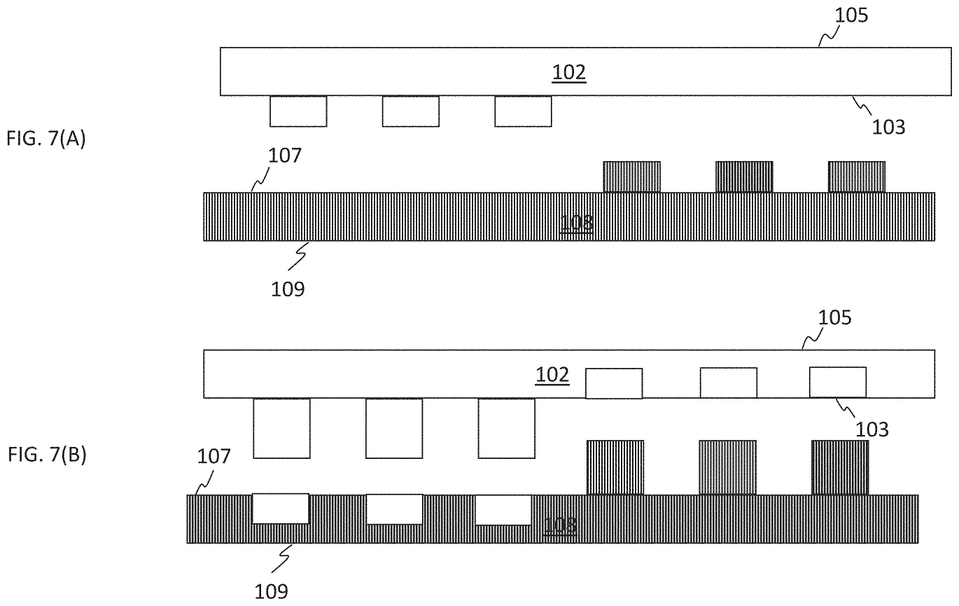

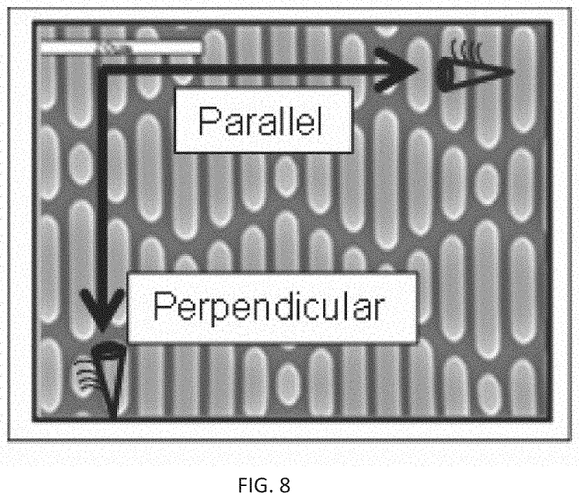

In another embodiment, a portion of the outwardly projecting features in a pattern are disposed on the first layer while the remainder of the outwardly projecting features in the pattern are disposed on the opposing second layer as seen in the FIG. 7(A). FIG. 7(B) shows two opposing layers where the outwardly projecting features on the first layer 102 interlock with the inwardly projecting features on an opposing second layer 108.

The surface energy of the respective surfaces 103 and 107 may be tailored by varying the size, geometry and orientation of the features on the surfaces. By varying the thickness “t”, the length “l”, the feature spacing “d” and the height “h” of the outwardly projecting features (or alternatively the depth “d” of the inwardly projecting features), the surface energy can be reduced or increased from that of the surface energy of an untextured polymer surface to facilitate adhesion with an opposing layer. In an embodiment, the composition of the features can be changed relative to the composition of the surface of the substrate (i.e., the layer on which the features are disposed).

For example the surface energy of a smooth solid polymeric surface comprising polydimethylsiloxane is 19.8 milliNewtons/meter. By texturing the surface with the disclosed patterns, the surface energy can be increased or decreased from the value of 19.8 milliNewtons/meter. Texturing the surface can therefore be used to increase or decrease the surface energy to facilitate adhesion with a barrier layer that facilitates a decrease in oxygen and/or water vapor transfer across the resulting multilayer film.

In an embodiment, the first layer 102 may be a polymer layer, a metal layer, a ceramic layer, or combinations thereof, while the second layer 108 may be a polymer layer, a metal layer, a ceramic layer, or combinations thereof. In an exemplary embodiment, the first layer 102 is a polymer layer, while the second layer 108 preferably comprises a metal layer.

Suitable metals are transition metals, platinum group metals, alkali metals, alkaline earth metals, or combination thereof. Examples of suitable metal layers include aluminum, copper, zinc, iron, steel, cobalt, titanium, nickel, palladium, gold, or alloys thereof.

Suitable ceramics include metal oxides, metal nitrides, metal carbides, metal silicides, metal borides, or mixtures thereof.

The first layer 102 may have a thickness of 100 nanometers to 200 micrometers, preferably 150 nanometers to 150 micrometers, and more preferably 200 nanometers to 100 micrometers. In an embodiment, the second layer 108 has a reduced thickness when compared with the first layer 102. The second layer 108 may have a thickness of 50 nanometers to 175 micrometers, preferably 100 nanometers to 150 micrometers, and more preferably 150 nanometers to 75 micrometers.

By varying the features, the adhesion between the first layer (with a surface texture) and the second layer (with or without the surface texture) may be increased or decreased over adhesion between the first layer and the second layer (where both the first surface and the second surface are devoid of any texture).

The ability to vary the surface energy at an interface between two layers is useful because it can be used to bond the two opposing surfaces without treatments that are expensive or time consuming such as those involving plasma treatments, radiation, chemical treatments involving strong acids, and the like.

In one embodiment, a first layer having the aforementioned textured surface is subjected to a process to form the second layer that contains a metal, a polymer or a ceramic. Exemplary processes to form the second layer includes coextrusion, cold rolling, chemical vapor deposition, plasma vapor deposition, atmospheric pressure CVD (APCVD), low-pressure CVD (LPCVD), ultrahigh vacuum CVD (UHVCVD), aerosol assisted CVD (AACVD), direct liquid injection CVD (DLICVD), microwave plasma-assisted CVD (MPCVD), metalorganic chemical vapor deposition (MOCVD), immersion in a salt bath (that contains the desired metal salt) followed by treatment in a reducing atmosphere, or a combination thereof.

Adhesion between two surfaces is dependent upon a variety of factors such as surface roughness of the mating surfaces, surface energy, pressure applied during the bonding process, and the like. In general surface roughening is used to facilitate adhesion between two surfaces. Surface roughening facilities mechanical interlocking between an adhesive layer and the roughened surface. In the instant disclosure, texturing of the surface can also be used to adjust the surface energy thereby adjusting the amount of energy that is used to bond the two surfaces and consequently to de-bond the two surfaces.

In an embodiment, the type of texture can be used to adjust the surface energy of a surface. For example, changing all vertical surfaces (of the texture) to inclined surfaces can change the surface energy and consequently the amount of energy used to facilitate adhesion.

Printing operations can then be conducted on the second layer if desired.

The multilayered article having a first layer that contains a polymer and a second layer that contains a metal are exemplified by the following example.

### EXAMPLE

This example is conducted to demonstrate the variation in the contact angle obtained by texturing a surface. The surface is textured using the texture described in this disclosure. The surface texture a) protrudes from the surface (has the designation SK), i.e., where the features extend outward from the surface or b) projected into the surface (has the designation (ISK), i.e., where the features extend into the surface. The surface energy is measured using contact angles.

The contact angle is measured in directions parallel and perpendicular to the texture as shown in the FIG. 8. Contact angles are also measured on smooth surfaces to determine the change in contact angle with texture.

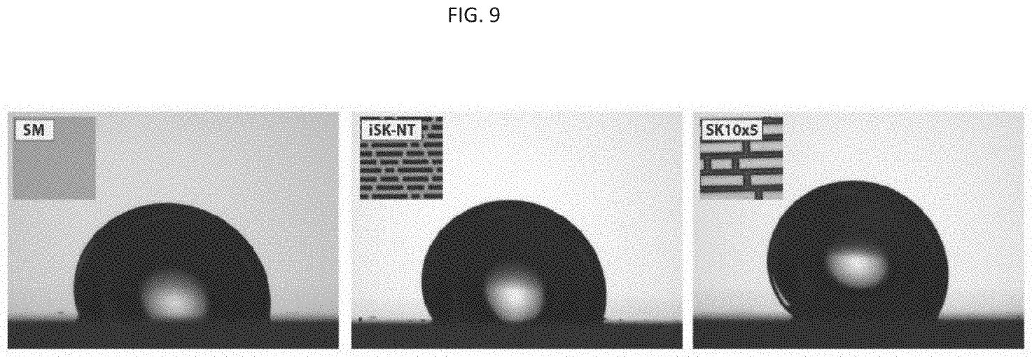

FIG. 9 shows the shape of the droplet on a) a smooth surface (indicated as SM), b) a surface where the texture is projected into the surface (indicated as ISK-NT) and c) a surface there the texture extends outwards from the surface (indicated as SK10×5).

The nomenclature adopted here (e.g., +1SK10×5) should deciphered as follows: The +1 indicates the height of the texture above the base surface while the SK refers to a Sharklet pattern depicted and described in U.S. Pat. No. 7,143,709 B2 to Brennan et al., and Patent Application having Ser. No. 12/550,870 to Brennan et al. A negative sign (−) preceding the 1 would indicate that the texture is below the base surface. The 10 in SK10×5 stands for the width of each feature in the pattern while the 5 stands for the spacing between the features in the pattern. All dimensions are in micrometers.

The +1 therefore indicates the dimension in micrometers (i.e., 1 micrometer) extending outwards from the surface, while the “10” indicates that the width of each feature is 10 micrometers and “5” indicates that the spacing between each feature is 5 micrometers.

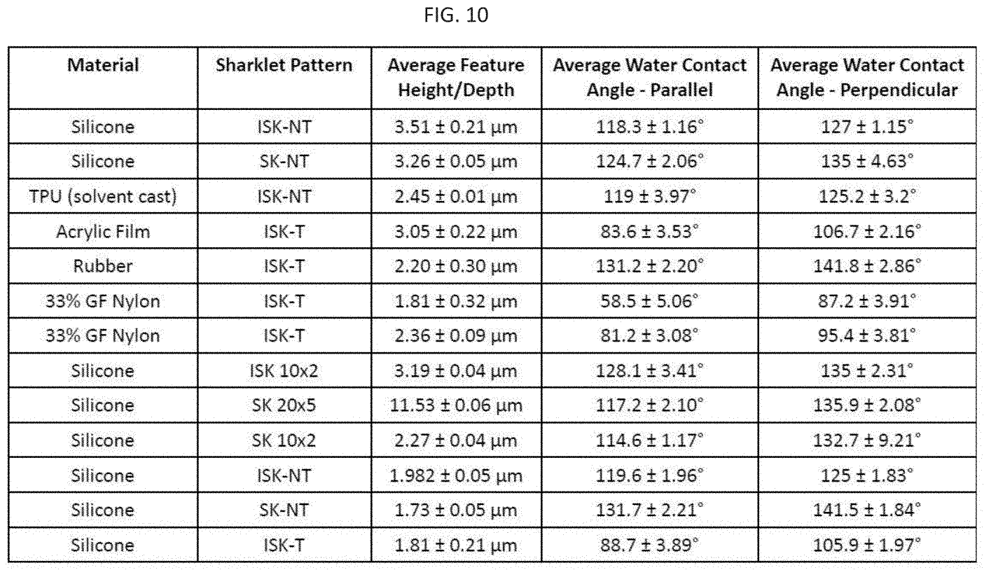

FIG. 10 shows a table which shows the measurements on a variety of different textured surfaces. The materials are silicone (polydimethylsiloxane), thermoplastic urethane (TPU), acrylic film, rubber, and 33% GF Nylon (polyamide containing 33% glass fibers). From the Table it can be seen that the change in the dimensions of the texture can cause significant differences in the contact angle. For example, textured surfaces comprising a silicone polymer and having textures of either SK20×5 or SK10×2 disposed on the silicone surface show that for the SK20×5, the contact angle in the parallel direction is 117 degrees, while it is 135 degrees in the perpendicular direction, while it is 114 degrees in the parallel direction and 132 in the perpendicular direction.

Similarly, the ISK10×2 surface and the SK10×2 surface show differences in the parallel and perpendicular direction respectively. Thus, the surface energy can be controlled by either making the texture protrude outwards from the surface or project into the surface.

1. A multilayered article comprising:
a first layer having a surface texture on a first surface; and
a second layer contacting the surface texture on the first layer; where the surface texture comprises a plurality of identical patterns; each pattern being defined by a plurality of spaced apart features attached to or projected into the first surface, at least one spaced apart feature having a dimension of about 1 nanometer to about 1 millimeter, the plurality of features each having at least one neighboring feature having a substantially different geometry, wherein each pattern has at least one feature which is identical to a feature of a neighboring pattern and shares that feature with the neighboring pattern, wherein an average spacing between adjacent spaced apart features is about 1 nanometer to about 1 millimeter in at least a portion of the first surface, wherein the plurality of spaced apart features are represented by a periodic function.

2. The article of claim 1, where the second layer comprises a metal.

3. The article of claim 1, where the second layer comprises a texture that is a negative image of the surface texture on the first surface.

4. The article of claim 1, where the second layer also comprises a surface texture; where the surface texture comprises a plurality of identical patterns; each pattern being defined by a plurality of spaced apart features attached to or projected into the second surface, at least one spaced apart feature having a dimension of about 1 nanometer to about 1 millimeter, the plurality of features each having at least one neighboring feature having a substantially different geometry, wherein each pattern has at least one feature which is identical to a feature of a neighboring pattern and shares that feature with the neighboring pattern, wherein an average spacing between adjacent spaced apart features is about 1 nanometer to about 1 millimeter in at least a portion of the first surface, wherein the plurality of spaced apart features are represented by a periodic function.

5. The article of claim 1, where the first layer comprises a polymer, a metal, a ceramic, or a combination thereof and where the second layer also comprises a metal, a polymer, a ceramic, but is different from the first layer.

6. The article of claim 1, where a distance between features is varied to change the surface energy of the first layer as well as the adhesion between the first layer and the second layer.

7. The article of claim 1, where a size of the features is varied to change the surface energy of the first layer as well as the adhesion between the first layer and the second layer.

8. A method comprising:
texturing a surface of a first layer to produce a textured surface; and
disposing a second layer to contact the textured surface of the first layer; where the surface texture comprises a plurality of identical patterns; each pattern being defined by a plurality of spaced apart features attached to or projected into the first surface, at least one spaced apart feature having a dimension of about 1 nanometer to about 1 millimeter, the plurality of features each having at least one neighboring feature having a substantially different geometry, wherein each pattern has at least one feature which is identical to a feature of a neighboring pattern and shares that feature with the neighboring pattern, wherein an average spacing between adjacent spaced apart features is about 1 nanometer to about 1 millimeter in at least a portion of the first surface, wherein the plurality of spaced apart features are represented by a periodic function.

9. The method of claim 8, where the second layer is disposed via coextrusion, cold rolling, chemical vapor deposition, plasma vapor deposition, atmospheric pressure CVD (APCVD), low-pressure CVD (LPCVD), ultrahigh vacuum CVD (UHVCVD), aerosol assisted CVD (AACVD), direct liquid injection CVD (DLICVD), microwave plasma-assisted CVD (MPCVD), metalorganic chemical vapor deposition (MOCVD), immersion in a salt bath (that contains the desired metal salt) followed by treatment in a reducing atmosphere, or a combination thereof.
